(19) United States
(12) Patent Application Publication
(10) Pub. No.: US 2013/0233373 A1
(43) Pub. Date: Sep. 12, 2013

(54) Concentrated Photovoltaic (CPV) Cell Module

(71) Applicant: CHANG GUNG UNIVERSITY, Tao-Yuan (TW)

(72) Inventors: Liann-Be Chang, Tao-Yuan (TW); Hsin-Chien Chen, Tao-Yuan (TW); Chun-Yi Tung, Tao-Yuan (TW); Fu-Ciang Yang, Tao-Yuan (TW)

(73) Assignee: CHANG GUNG UNIVERSITY, Tao-Yuan (TW)

(21) Appl. No.: 13/779,305

(22) Filed: Feb. 27, 2013

(30) Foreign Application Priority Data
Mar. 6, 2012 (TW) 101107543

(51) Int. Cl. H01L 31/052; H01L 31/058

(52) U.S. Cl. CPC H01L 31/0524; H01L 31/058
USPC 136/248; 136/246

(57) ABSTRACT

A concentrated photovoltaic (CPV) cell module, comprising: a shell; a Fresnel lens set, provided on top of said shell; a first solar cell, provided on bottom of said shell and opposite to said Fresnel lens set; and at least a second solar cell, provided on surrounding wall and/or bottom of said shell, so that area originally not capable of generating power is able to generate power, to raise power generating capacity per unit area of said concentrated photovoltaic (CPV) cell module.

### BACKGROUND OF THE INVENTION

1. Field of the Invention

The present invention relates to a concentrated photovoltaic (CPV) cell module, and in particular to a concentrated photovoltaic (CPV) cell module capable of raising photoelectric efficiency per unit volume of the CPV cell.

2. The Prior Arts

With the development of the concentrated lens system, plus the raise of photovoltaic (solar) cell efficiency, the concentrated solar cell system has great potential to be developed into a large scale power plant. Due to the increased light concentration, input power of the sunlight can be raised by several to hundred times of the original input power, therefore, the area occupied by the solar cell elements can be reduced, as such solving the problem of high price of solar cell material. In this respect, Taiwan is suitable of developing various types of concentrated photovoltaic (CPV) cells, for having reached such a high level of research and development for semiconductor solar energy. In the Specification, photovoltaic cell and solar cell are used interchangeably to facilitate understanding of the subject.

Among the regenerated energy resources, the concentrated photovoltaic (CPV) power generating system has great potential for further development, for having the advantages of saving solar cell material, reduced power generating cost, and raised power generating efficiency, so it is suitable to be used to make a solar cell power plant, and can be considered as the key point of development of solar energy Industry for the future. The combination of Group III-V semiconductor solar cell or silicon crystal solar cell of low cost, with the Fresnel Lens, to a CPV power generating system has caught the attention of the Industries for being capable of reducing power generating cost significantly.

Refer to FIG. 1 for a perspective view of a concentrated photovoltaic (CPV) cell module according to the prior art. As shown in FIG. 1, the CPV cell module 10 includes: a packaging shell 12, a Fresnel Lens set 14, a Group III-V semiconductor solar cell 11, and a heat dissipation substrate 13. Wherein, the rigid and solid packaging shell 12 made of metal is used for packaging, to protect the elements inside. The Fresnel Lens set 14 on top of the module 10, is of light-weight and thin-profile, to replace the conventional optical lens, so in addition to reducing large amount of weight and volume, it has the benefit of fast production at reduced cost. In the position opposite to the Fresnel Lens set 14 is the Group III-V semiconductor solar cell 11 of smaller area, so that when irradiated by sun light, the Fresnel Lens set 14 is able to focus and concentrate sunlight on the Group III-V semiconductor solar cell 11 to generate and output power, for the consumption of the subsequent electronic devices. Also, the heat generated in this process can be dissipated through a heat dissipation substrate 13 on the bottom of the Group III-V semiconductor solar cell 11.

The major characteristics of CPV cell is to emphasize the benefit of producing high power per unit area of CPV cell. However, the surface area on the outer side of the CPV cell module is wrapped and covered with packaging shell to protect the solar cells inside. In other words, the packaging shell shields the sunlight and reduce the overall power generating capacity of the system.

Therefore, presently, the design and performance of the concentrated photovoltaic (CPV) cell of the prior art is not quite satisfactory, and it has much room for improvements.

### SUMMARY OF THE INVENTION

In view of the problems and shortcomings of the prior art, the present invention provides a concentrated photovoltaic (CPV) cell module, to overcome the problem of the prior art,

A major objective of the present invention is to provide a concentrated photovoltaic (CPV) cell module, such that the area originally shielded and not having power generating capability is provided with solar cells, to raise the overall power generating capacity per unit area for the CPV cell module.

In order to achieve the above-mentioned objective, the present invention provide a concentrated photovoltaic (CPV) cell module, comprising: a shell; a Fresnel lens set provided on top of the shell; a first solar cell disposed at bottom of the shell and opposite to the Fresnel lens set, and the first solar cell is located inside the shell; and at least a second solar cell provided on the surrounding wall and/or the bottom of the shell.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a perspective view of a concentrated photovoltaic (CPV) cell module according to the prior art;

FIG. 2 is a schematic diagram of a concentrated photovoltaic (CPV) cell module packaging structure according to the first embodiment the present invention;

FIG. 3 is a schematic diagram of a concentrated photovoltaic (CPV) cell module packaging structure according to the second embodiment the present invention;

FIG. 4 is a schematic diagram of a concentrated photovoltaic (CPV) cell module packaging structure according to the third embodiment the present invention;

FIG. 5 is a schematic diagram of a concentrated photovoltaic (CPV) cell module packaging structure according to the fourth embodiment the present invention;

FIG. 6 is a schematic diagram of a concentrated photovoltaic (CPV) cell module packaging structure according to the fifth embodiment the present invention; and

FIG. 7 is a schematic diagram of a concentrated photovoltaic (CPV) cell module packaging structure according to the sixth embodiment the present invention.

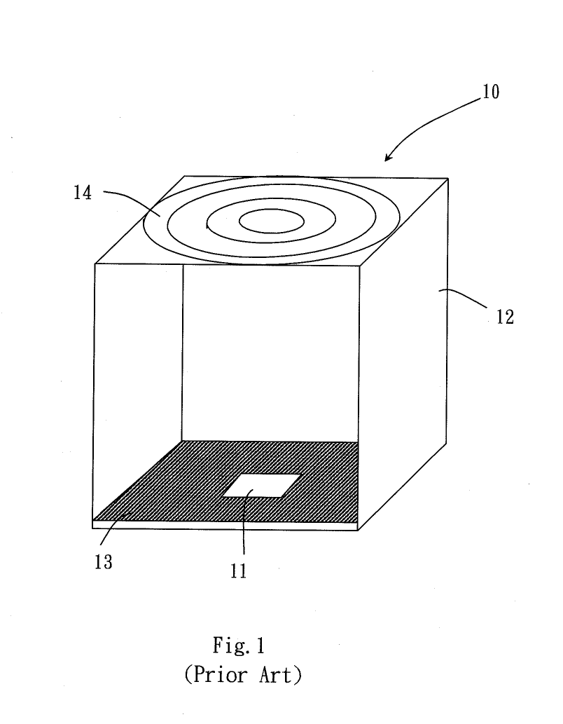

### DETAILED DESCRIPTION OF THE PREFERRED EMBODIMENT

The purpose, construction, features, functions and advantages of the present invention can be appreciated and understood more thoroughly through the following detailed description with reference to the attached drawings. And, in the following, various embodiments are described in explaining the technical characteristics of the present invention.

The essence of the present invention is that, in addition to the concentrated photovoltaic (CPV) cell module, other power generation components are additionally added, so that the area originally shielded and not having power generating capability is provided with solar cells, to raise the overall power generating capacity per unit area for the CPV cell module.

In other words, in addition to the Fresnel Lens set and the opposite Group III-V semiconductor solar cell, the present invention provides additional solar cells, such as thermal-electric solar cell, thin-film solar cell, or silicon solar cell, etc. However, the present invention is not limited to this.

In other to reduce cost further, in addition to the conventional Fresnel Lens set, the Group III-V semiconductor solar cell of the present invention can be a thin-film solar cell, a poly-silicon solar cell, a mono-silicon solar cell, or an amorphous silicon solar cell. However, the present invention is not limited to this.

In the following, various embodiments of the present invention are described in detail.

### Embodiment 1

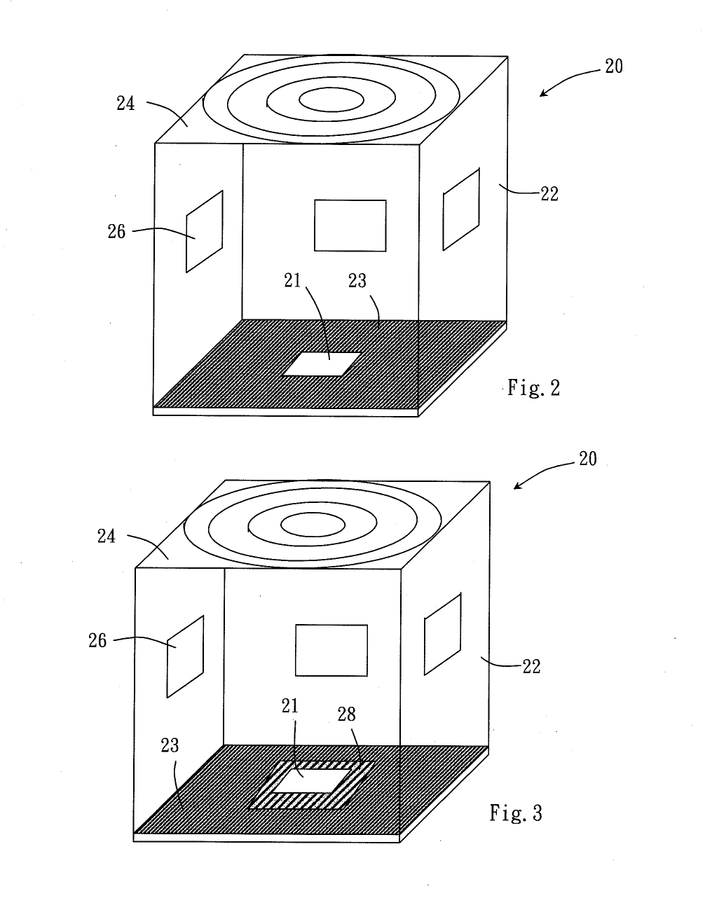

Refer to FIG. 2 for a schematic diagram of a concentrated photovoltaic (CPV) cell module packaging structure according to the first embodiment of the present invention. As shown in FIG. 2, the concentrated photovoltaic (CPV) cell module packaging structure 20 includes a shell 22, a Fresnel Lens set 24, a first solar cell 21, and at least a second solar cell 26. Wherein, the shell 22 is made of transparent material that is corrosion-resistant, base-and-acid resistant, and high-temperature resistant. The Fresnel Lens set 24 is provided on top of the shell 22. The first solar cell 21 is located opposite to the Fresnel Lens set 24, it can be a high efficiency Group III-V semiconductor solar cell, and is disposed inside and on the bottom of the shell 22. And the at least a second cell 26 is provided on the surrounding wall of the shell 22.

The second solar cell 26 mentioned above can be various types of solar cells, for example, a poly-silicon solar cell; a mono-silicon solar cell; or thin-film solar cell, such as an amorphous silicon solar cell, a microcrystalline silicon solar cell, a dye-sensitized solar cell (DSSC), an organic polymer solar cell, and solar cell made of Group II-VI semiconductor, such as CdTe, CuInSe₂, or CuInGaSe₂, or Group III-V semiconductor, or compound thereof; or thermal-electric solar cell, flexible solar cell, or various types of solar cells having large surface area.

In the structure mentioned above, the second solar cell 26 is provided on the surrounding wall of the shell 22, so that for the same volume, more sunlight energy can be received. Also, the scattered and reflected sunlight in the module can be received, to achieve more power generation per unit area.

The first solar cell 21 can be an ordinary silicon crystal solar cell, a thin film solar cell, a poly-silicon solar cell, a mono-silicon solar cell, or an amorphous silicon solar cell, that is arranged opposite to the Fresnel Lens set 24, to convert sunlight into electric power and output the power. When the first solar cell 21 is a Group III-V semiconductor solar cell, compared with the ordinary silicon crystal solar cell, it can absorb sunlight energy of a wider spectrum, to raise the photo-electric conversion efficiency significantly.

The Group III-V semiconductor solar cell can be made of materials selected from a group consisting of: GaAs, GaP, InP, AlGaAs, GaInAs, AlGaP, GaInP, AlGaAsP, InGaAsP, AlGaInAsP, and combinations thereof; or it can be made of materials selected from a group consisting of: GaN, InN, GaAl, AlGaN, AlInN, AlInGaN, and combinations thereof. At this time, a substrate 23 can be disposed, that is a heat dissipation substrate of good heat dissipation capability, and is made of material, such as Ag, Cu, Al, Ni, Au, or alloy thereof. Therefore, the high temperature of the first solar cell 21 caused by the light concentrated by the Fresnel Lens set 24 can be dissipated through the substrate 23 into the surrounding air out of the shell 22.

When sunlight is focused through the Fresnel Lens set 24, it will be concentrated on the first solar cell 21, to increase its photo-electric conversion efficiency significantly. Meanwhile, the surrounding wall of the module is provided with the second solar cells 26 of various types, to receive the sunlight coming from outside, and the scattered and reflected sunlight inside after focusing to produce electric power, thus achieving more output power.

### Embodiment 2

Refer to FIG. 3 for a schematic diagram of a concentrated photovoltaic (CPV) cell module packaging structure according to the second embodiment of the present invention. The difference between the present embodiment and that of FIG. 2 is that, a thermal-electric third solar cell 28 is disposed between the first solar cell 21 and the bottom of the shell 22. Therefore, the heat energy produced by the first solar cell 21 after being irradiated by the focused sunlight can be received and converted directly into electrical power through the third solar cell 28.

### Embodiment 3

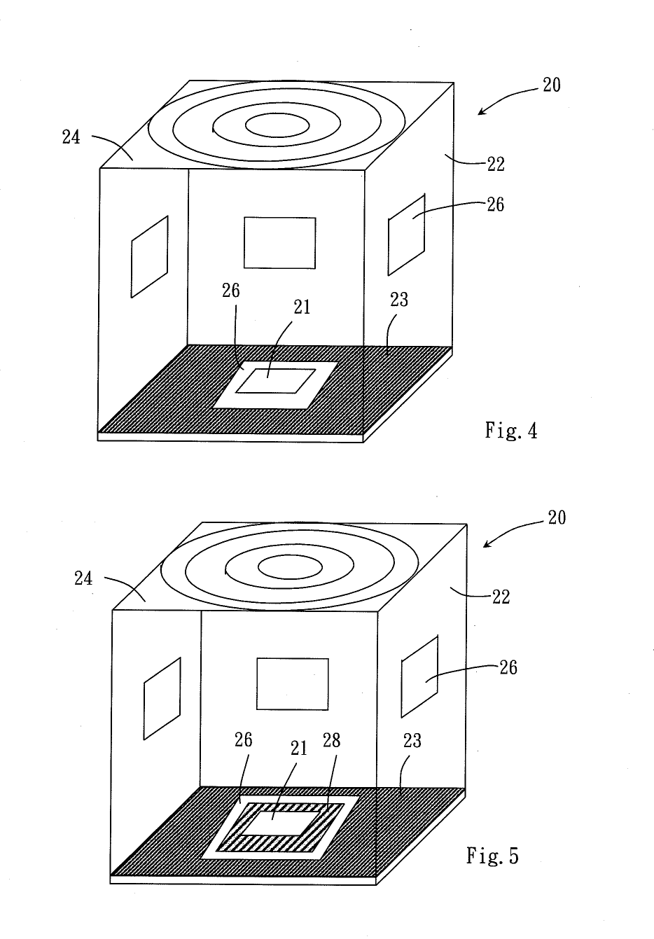

Refer to FIG. 4 for a schematic diagram of a concentrated photovoltaic (CPV) cell module packaging structure according to the third embodiment of the present invention. The difference between the present embodiment and that of FIG. 2 is that, a second solar cell 26 is provided at the bottom of the shell 22, and is disposed on the surroundings of the first solar cell 21, to absorb the sunlight not absorbed by the first solar cell 2, so as to generate power.

### Embodiment 4

Refer to FIG. 5 for a schematic diagram of a concentrated photovoltaic (CPV) cell module packaging structure according to the fourth embodiment of the present invention. As shown in FIG. 5, the present embodiment is a combination of the embodiments mentioned above. The second solar cells 26 are provided on the bottom and surrounding walls of the shell 22, and a thermal-electric third solar cell 28 is disposed between the first solar cell 21 and the bottom of the shell 22.

### Embodiment 5

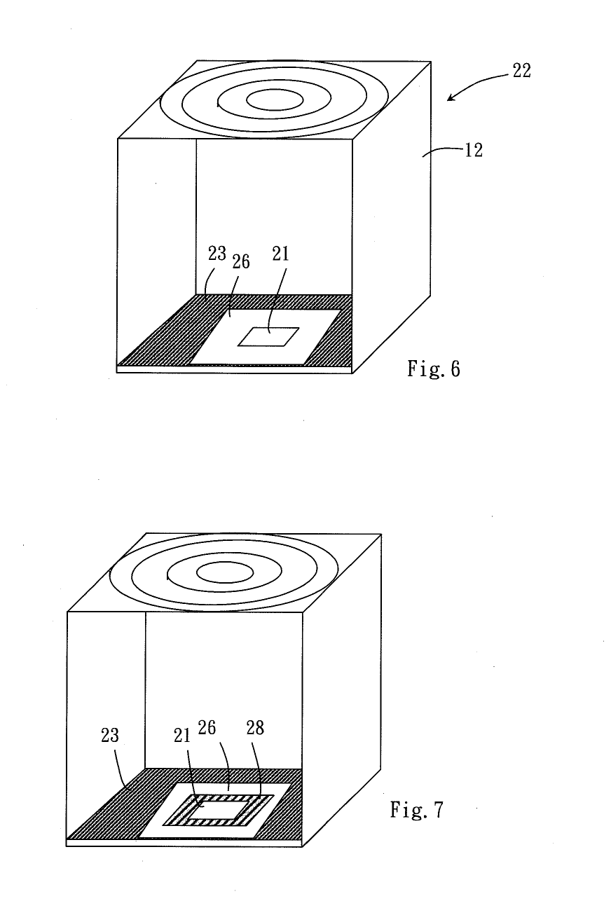

Refer to FIG. 6 for a schematic diagram of a concentrated photovoltaic (CPV) cell module packaging structure according to the fifth embodiment of the present invention. In the present embodiment, only an unspecified type second solar cell 26 is disposed on the bottom of the shell 22, with its surrounding wall made of metal material, the same as that of packaging shell 12 of the prior art.

The essence of the present embodiment is that, the second solar cell 26 is only disposed on the bottom of the shell 22, it is not required to be disposed on the surrounding wall. Of course, it can be inferred that, the second solar cell 26 can only be disposed on one side of the surrounding wall.

### Embodiment 6

Refer to FIG. 7 for a schematic diagram of a concentrated photovoltaic (CPV) cell module packaging structure according to the sixth embodiment of the present invention. The difference between the present embodiment and that of FIG. 6 is that a thermal-electric third solar cell 28 is disposed between the first solar cell 21 and the second solar cell 26, to increase the generated output power.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A concentrated photovoltaic (CPV) cell module, comprising:
a shell;
a Fresnel lens set, provided on top of said shell;
a first solar cell, provided on bottom of said shell; and
at least a second solar cell, provided on surrounding wall and/or bottom of said shell, and is located inside said shell.

2. The concentrated photovoltaic (CPV) cell module as claimed in claim 1, wherein said first solar cell is a Group III-V semiconductor solar cell.

3. The concentrated photovoltaic (CPV) cell module as claimed in claim 2, wherein said Group III-V semiconductor solar cell is made of materials selected from a group consisting of: GaAs, GaP, InP, AlGaAs, GaInAs, AlGaP, GaInP, AlGaAsP, InGaAsP, AlGaInAsP, and combinations thereof.

4. The concentrated photovoltaic (CPV) cell module as claimed in claim 2, wherein said Group III-V semiconductor solar cell is made of materials selected from a group consisting of: GaN, InN, GaAl, AlGaN, AlInN, AlInGaN, and combinations thereof.

5. The concentrated photovoltaic (CPV) cell module as claimed in claim 1, wherein said first solar cell is a thin-film solar cell, a poly-silicon solar cell, a mono-silicon solar cell, or an amorphous silicon solar cell.

6. The concentrated photovoltaic (CPV) cell module as claimed in claim 5, further comprising:
a third solar cell, disposed between said second solar cell and bottom of said shell, and said third solar cell is a thermal-electric solar cell.

7. The concentrated photovoltaic (CPV) cell module as claimed in claim 1, wherein said second solar cell is selected from said thermal-electric solar cell, said thin-film solar cell, or a silicon solar cell.
